(19) United States
(12) Patent Application Publication
(10) Pub. No.: US 2013/0258319 A1
(43) Pub. Date: Oct. 3, 2013

(54) NEEDLE PROBE FOR ANALYSIS OF MULTIPHASE FLOWS, PRODUCTION AND USE OF NEEDLE PROBE

(71) Applicant: HELMHOLTZ-ZENTRUM DRESDEN - ROSSENDORF E.V., Dresden (DE)

(72) Inventors: Eckart SCHLEICHER, Dresden (DE); Stefan KAYSER, Jonsdorf (DE)

(73) Assignee: Helmholtz-Zentrum Dresden - Rossendorf e.V., Dresden (DE)

(21) Appl. No.: 13/855,292

(22) Filed: Apr. 2, 2013

(30) Foreign Application Priority Data
Apr. 2, 2012 (DE) 10 2010 102 870.2

(51) Int. Cl. G01R 1/067; G01N 21/85

(52) U.S. Cl. CPC G01R 1/06711; G01N 21/85
USPC 356/72

(57) ABSTRACT

A triaxial constructed needle probe for reliable differentiation of multiphase media, comprises a probe body having a central light conductor having a metallic surface and a distal end of which is to be inserted in the medium, a first electrically insulating sheath disposed around the optical fiber, a hollow cylindrical shield electrode arranged around the first insulating sheath, a second electrically insulating sheath arranged around the shield electrode, and a hollow cylindrical reference electrode arranged around the second insulating sheath, as well as a measuring circuit for measuring the optical refractive index and electrical conductivity of the medium.

### BACKGROUND OF THE INVENTION

This invention relates to a needle probe in an arrangement for analysis of and discrimination between phases of multiphase flows, and the production and the use of the needle probes. By “multiphase flow” is meant a flowing medium constituted of a plurality of phases constituted of respective different components (i.e., different gases such as air or other gas, and liquids).

The determination of the structure and the individual phase components of multiphase flows is mainly important during operation in processing, petrol-chemical, or thermo-hydraulic systems, where the phase distribution of multiphase flows is an important to be measured parameter in monitoring or control of the process flow or of the safety of a thermal-hydraulic system.

DE 32 01 799 C Aug. 8, 1983], DE 19 704 609 C Jan. 10, 2002 and DE 44 93 861 C Apr. 2, 2003] describe needle probes with coaxial design for measuring conductivity based on the measurement of a direct or alternating current flowing between the metallic probe tip and the outer reference electrode. These technical solutions are used only for detecting the conductivity and therefore are not suitable for the differentiation of non-conductive fluids.

Da Silva, M. J. et al.: A novel needle probe based on high-speed complex permittivity measurements for investigation of dynamic fluid flows. IEEE Transactions on Instrumentation and Measurement 56(2007) 4, pp. 1249 to 1256.] describes a capacitive measuring needle probe, which allows measuring the electrical permittivity of the surrounding medium. Reliable discrimination between all three components is difficult using the capacitive needle probe, but certainly not possible in a timely manner because the components have high dynamic differences, for example, the dynamic range of air with the value 1 differs from that of oil—about 2, and that of water—about 80.

U.S. Pat. No. 5,995,686 A Nov. 30, 1999], U.S. Pat. No. 5,005,005 A Apr. 2, 1991 and U.S. Pat. No. 4,851,817 A Jul. 25, 1989] A describe optical probes that are designed for the determination of local or global refractive index or the temporal change in an analysis medium. Light from a transmitter element is irradiated in a light-conducting element, and either the transmitted intensity at the other end of the light conducting member is measured, the light-guiding element having been manipulated so that a portion of the light in dependence on the refractive index can emerge from the light-guiding element, or the exposed other end of the light conducting member is used as a sensor which depends on the refractive index of the medium wherein intensity of reflected light is determined with use of a fiber splitter and a detector. Gases and liquids can be well differentiated from each other as relatively light conducting and non-conducting respectively, with these arrangements. Distinguishing different fluids with a similar refractive index is only conditionally possible.

DE 100 12 938 A1] describes a needle-like probe, wherein the central exciting electrode is designed as an insulated sheath thermocouple, wherein the electrically conductive sheath of the thermocouple is used as the excitating electrode for the measurement of conductivity and the temperature is measured as a differential voltage between the inside of the sheath thermocouple and the outer electrode, in which wires serving the thermocouple and the outer electrode are connected at the same reference potential. Due to the increased thermal inertia of the temperature probe as a result of the thermal resistance of the insulating material between the thermocouple jacket and the thermocouple wires, synchronous conductivity and temperature measurement is not possible.

DE 10 2005 046 662 B3] describes a coaxially arranged needle probe and thermocouple for measuring the electrical impedance and temperature of fluids, wherein at the thermal contact point at the tip of the probe the two wires formed by the thermocouple wires center conductor are in direct thermal or electrical contact with the medium.

DE 102 010 030 131 A1] describes a hand-held device for penetrating a heat-insulating layer of a corrodible metal article and for inspecting the metal article, especially a pipe, for corrosion. Evidence of rust is preferably obtained by application to the plate of a coating of penetrating carrier material (gel nonwoven), which ensures the chemical detection of the iron ions, then analyzed by spectroscopy.

### SUMMARY OF THE INVENTION

Industrial mixtures to be tested mixtures are usually not made up of only two components.

An object of the present invention is to provide an arrangement ensuring a reliable differentiation and measurement of multiphase mixtures, primarily gaseous and liquid phases. For example, the mixture may consist of a gaseous phase and two liquid phases.

The object is achieved by the use of a needle probe which enables both the determination of the gaseous phase and the liquid phases.

The needle probe comprises a needle probe body having a central optical (light) conductor, having a metal jacket or sheath, the terms being used interchangeably herein, 6 forming a metal surface of the light conductor and a tip of which metal-sheathed light conductor is to be inserted in a multiphase medium, a first insulator (electrically insulating sheath) arranged around the metal-sheathed light conductor, a hollow cylindrical shield electrode 2 arranged around the first insulating sheath, a second insulator (electrically insulating sheath) arranged around the shield electrode, and a hollow cylindrical reference electrode, and a measuring circuit to which the needle probe body is connected to, wherein the measuring circuit evaluates both the optical refractive index characteristics of the medium and the conductivity of the medium. The term “metallized” is used herein in a conventional sense to mean that the metal, which is electrically conductive, has been coated onto the optical conductor, typically optical fiber, and therefore adheres thereto. Alternatively, the metal sheath or jacket may be a separate metal tube to which the optical conductor does not adhere and into which the optical conductor has been threaded or the like.

The liquid phases can then be reliably distinguished based on their conductivity or permittivity, and the gas phases based on their refractive index. The sensor is thus very robust against interference, because the two signal components (refractive index, and electrical impedance or permittivity) can be binarized, making an elaborate calibration and temperature compensation unnecessary.

The presence of suspended solids in the multiphase mixture does not interfere with the measurement results if the concentration of suspended solids is low.

The gas and liquid phases can be correctly detected.

### BRIEF DESCRIPTION OF THE DRAWINGS

FIG. 1 shows the inventive needle probe for rapid and simultaneous measurement of the local electrical impedance and the refractive index of fluids necessary for the measurement with the measuring device.

FIG. 2 shows the results using a prototype for the measurement.

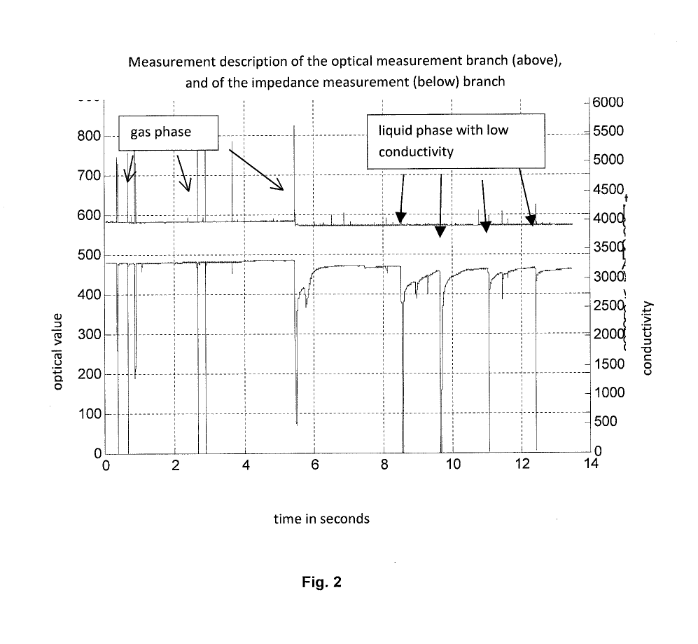

FIG. 3 shows a scheme for the evaluation of the measured values.

FIG. 4 illustrates the identification of the parallel evaluation of the respective phases.

FIG. 5 shows photos of a prototype of a needle probe.

### DETAILED DESCRIPTION OF THE INVENTION

The probe preferably has, for the purpose of measuring, a coaxial structure, which, as there are three active elements apart from insulation, namely, the metal-sheathed light conductor, the shield electrode, and the reference electrode, may be referred to as “triaxial”. Serving as the central tip of the probe body is a metallically-sheathed optical fiber whose metallic sheath serves as an electrode for impedance measurement. It is surrounded by an insulating sheath. About that a shield electrode is arranged, which is in turn is surrounded by an insulating sheath. Radially farthest out is a reference electrode. The tip of the probe body is in direct contact with the surrounding medium. Measuring means of the probe of the invention includes means for evaluation of the refractive index of the medium and means for the impedance measurement of the medium.

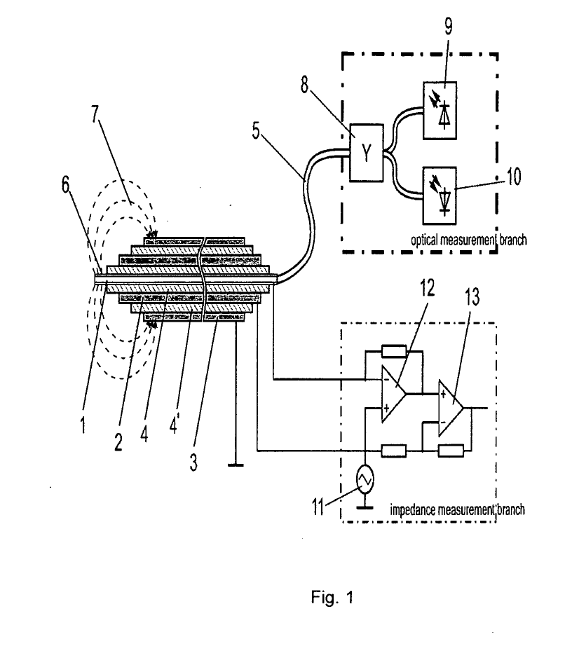

The arrangement of the invention, shown in FIG. 1, consists of a triaxial needle probe body, comprising a central light conductor 1 having a metal surface formed by a metal sheath 6 which metal-sheathed light conductor is to be inserted into the assay medium, about the optical fiber 1 a hollow cylindrical shield electrode 2 electrically insulated from the metallized surface 6 by means of an insulator 4, and about the shield electrode 2 a hollow cylindrical reference electrode 3 electrically insulated from the shield electrode 2 by means of a second insulator 41, as well as a measuring circuit comprising an optical measuring branch and an impedance measuring branch. A pressure-resistant sealing disc (not shown) having a central opening receives the metallically sheathed light conductor which passes through the central opening and is connected to the metallic sheath preferably by soldering or welding to provide a pressure-resistant seal at the head of the probe.

The impedance measuring branch includes an AC voltage source 11, a transimpedance amplifier 12 and a differential amplifier 13.

Ideally, the optical measurement branch comprises an optical transmitter 9 and an optical receiver 10, wherein the transmitting and receiving optical signals can be separated by an optional optical coupler 8.

In the arrangement of the invention, the metal jacket 6 of the light conductor 1 is electrically connected to the inverting input of a high-impedance transimpedance amplifier 12, the shield electrode 2 is electrically connected to the non-inverting input of the transimpedance amplifier 12, and the reference electrode 3 is electrically connected to the ground potential of the circuit. Applied to the shield electrode 2 is a rectangular, trapezoidal or sine wave AC voltage of an AC low voltage source 11. Due to the transimpedance amplifier having a feedback impedance Zf between the inverting input and output such that a virtual short circuit of the operational amplifier inputs is created, it is ensured that exciting AC voltage of approximately the same phase is applied to the shield electrode 2 and the surface of the metal sheath 6 of the light conductor 1. Between the surface of the metal sheath 6 and the reference electrode 3, an electric field is created, wherein the field lines 7 concentrate as desired at the probe body tip about the tip of the optical fiber 1, while the shield electrode 2 provides for displacement of the field lines 7 away from the probe body interior and from the interface of the probe tip of the probe with the rest of the probe body. Relating to the electrical impedance of the surrounding medium on the probe tip, is a corresponding current flow, which, from the transimpedance amplifier 12, is converted into an equivalent output voltage. By means of a differential amplifier 13, the excitation signal will be subtracted from the measurement signal, so that the difference signal is a linear measure of the current flow to the probe tip, and thus the impedance of the medium. The output of the differential amplifier 13 can be connected to an analog digital converter.

The output of the transimpedance amplifier can be connected to an I/Q demodulator, which outputs the real and imaginary components of the AC voltage signal as measured values.

Simultaneously, an optical signal is injected into the optical conductor 1 by an optical transmitter 9 via an optical cable 5 as well as an optical coupler 8, by. At the tip of the needle probe this optical signal exits from the optical conductor. A part of the light, however, at the boundary surface in between the light conductor 1 and the surrounding medium is reflected back into the optical waveguide (conductor) 1. The reflected portion depends on the refractive index of the surrounding medium. With a large refractive index (liquid) a large part of the light exits from the light conductor 1. At a low refractive index (gas) of the surrounding medium a greater proportion of the light is reflected back at the interface into the optical guide 1, and through the optical cable 5 and the optical coupler 8 is transported to the optical receiver 10 and converted there into a usable electrical signal. The output voltage of the optical receiver 10 is thus a measure of the refractive index of the surrounding medium.

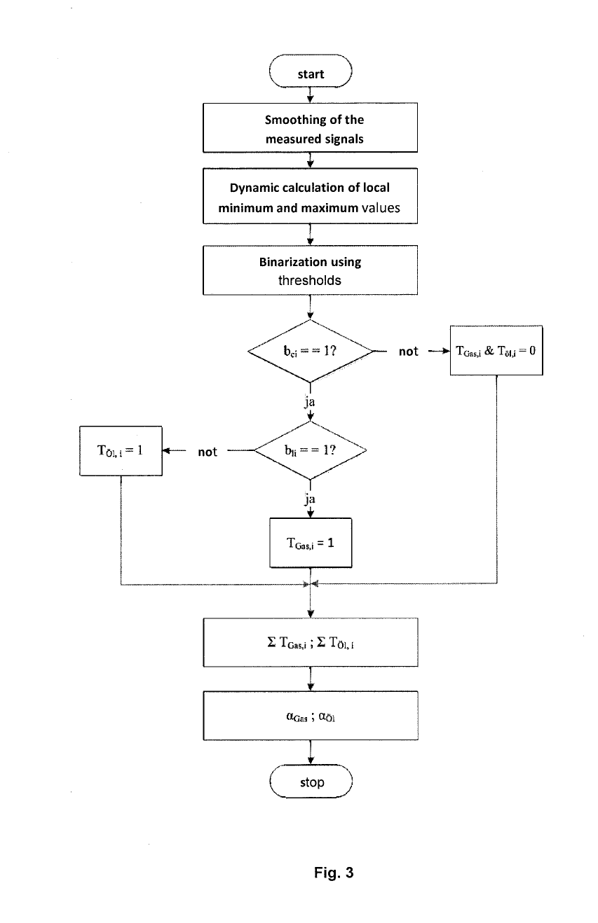

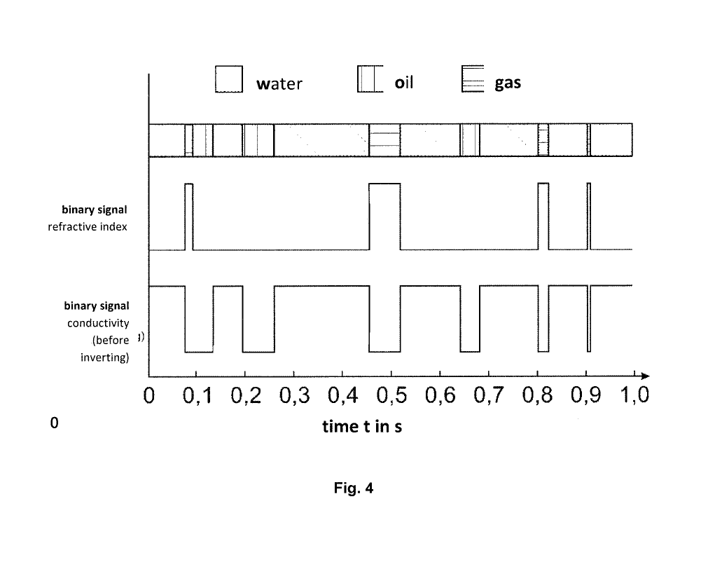

For phase discrimination the output signals of the two measuring branches are binarized continuous timewise, wherein the output voltage of the optical receiver in gas phase is represented as an upward rising signal and the difference signals from the impedance measuring branch in respective different liquid phases are represented as downward falling signals, see FIG. 3 and FIG. 4. The binarization is effected by means of two threshold values (sₓ₊, sₓ₋), which are formed by appropriate threshold values strokes of the respective signal, which are determined by the difference between the maximum and minimum values of the respective output signals of the measuring branches.

Binarization of the output signal of the optical measurement branch is such that a high-active binary signal represents the binarized output voltage for the gas phase at the measurement time point. The change of state from the low-to high-active area of the binary signal of the optical measuring branch occurs when increasing output signal by a phase change from liquid to gas phase in the rising flank of the output voltage.

b_{↓}(optical, xi)={▪(x_{↓}i<s₁(x−)=1@x_{↓}i<s_{↓}(x+)=0)bₓᵢ∈{0,1}

The binarization of output signal of the impedance measurement branch takes place so that a high-active binary signal of the output voltage represents the impedance changes. The state change from the low-to high-active area of the binary signal of the impedance measuring branch occurs at phase change with falling output signal at the falling flank of the binarized differential voltage. Thereafter the binarized conductivity signal is inverted.

b_{↓}(electrical, xi)={▪(x_{↓}i>s_{↓}(x+)=1@x_{↓}i<s_{↓}(x−)=0)bₓᵢ∈(0,1)

The phase discrimination is carried out via the continuous-time comparison of the signal state of the binary signals of the optical measurement branch and of the impedance measuring branch. A continuous-time high-active area of the two binary signals defines a discrete time interval of the gas phase. Thus a period of time (T_{gas phase}) is the gas phase, described as a logical AND operation of the binary signals of the optical measurement branch and of the impedance measuring branch.

$${T}_{gas phase} = {\sum }_{i} [ ( {b}_{optical} ⋃ {b}_{electrical} ) = 1 ]$$

A change of fluid is represented by a state change in the binary signal of the impedance measuring branch with at the same time low-active signal state of the binary signal of the optical measuring branch. A period of time of a non-conductive liquid phase (T_{liquid, non-conductive}) is now described as a logical-subtraction of the binary signals of the optical measurement branch and of the impedance measuring branch.

$${T}_{liquid , non - conductiv} = {\sum }_{i} [ ( {b}_{optical} - {b}_{electrical} ) = 1 ]$$

Concerning the length of time of the total measurement period, not only the time period of the gas phase and of the non-conductive liquid phase, but also that of a third phase (conductive fluid) of the flowing mixture is to be considered. The certain periods of time of the corresponding phases relative to the total time span of the measurement period are available for determining the local phase contents. The local content of a phase is the quotient of the time period of the phase and the total time span of the measurement period.

$$α ( xi ) = {lim}_{T \to ∞} ( \frac{{\sum }_{i} {T}_{xi}}{T} )$$

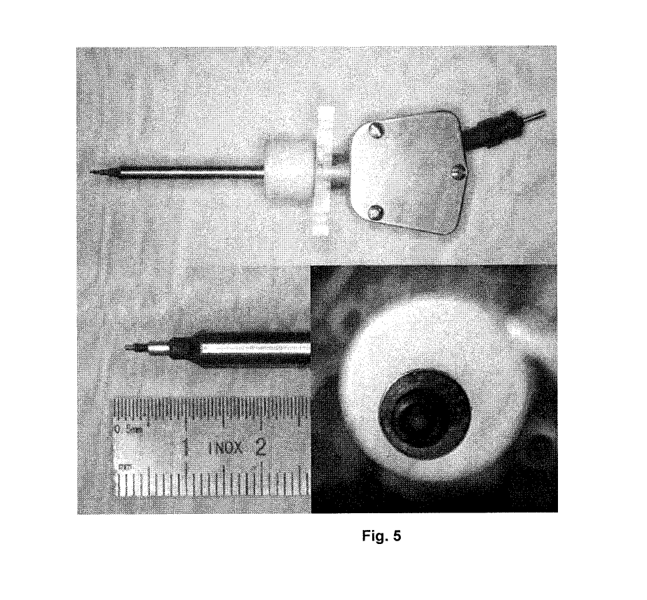

As an example, a prototype (FIG. 5) has been constructed based on copper-clad optical fiber. The conductive copper coating was thereby directly used as the measuring electrode. This enabled providing a small tip in comparison to other probes. It follows that the diameters of shield and reference electrodes could also be smaller. Due to this smaller size it is to be expected that the components of the multi-phase flow move well, i.e., substantially unimpeded, past the probe tip. The combination of fiber and copper coating is also easy to work with. Thus, a good optical signal quality is to be expected. From the firm bond of the copper layer with the quartz glass optical fiber, a uniquely strong and stable probe tip is provided. Instead of quartz glass, polymer fibers have been used in embodiments of the invention. The use of steel tubes for the inner (reference) and outer (shield) electrodes is possible. The probes were successfully tested in various positions of insertion into a gas-liquids multiphase flowing mixture, namely, orthogonally from directly above, orthogonally directly from the side, or at an incident angle, wherein the passage of phases at the probe tip was examined by camera.

Potential applications of the sensor are the measurement of the composition of mixtures and their degree of dispersion (for example, an oil-water-gas mixture in crude oil or liquid reagents in physical and chemical manufacturing processes), or the detection of impurities in single-phase media.

The functionality has been proven in extensive tests with different prototypes.

FIG. 4 illustrates the detection of the individual phases in a multiphase flow. In the upper area of this figure each phase displayed is detected by evaluation (processing) of the signals of the optical and impedance measuring branches of the measuring circuit.

1.-7. (canceled)

8. A needle probe for analysis of a flowing multiphase medium comprising a plurality of phases constituting a plurality of respective components, the needle probe comprising a needle probe body having a central light conductor, a metal sheath surrounding the central light conductor and a distal end of which metal-sheathed light conductor is situated at a head of the probe body for insertion in the multiphase medium, a first electrically insulating sheath arranged around the metal-sheathed light conductor, a hollow cylindrical shield electrode arranged around the first insulating sheath, a second electrically insulating sheath arranged around the shield electrode, and a hollow cylindrical reference electrode arranged around the second insulating sheath, the needle probe further comprising a measuring circuit optically and electrically connected to the needle probe body and having an optical measuring branch and an impedance measuring branch, wherein:
a. the optical measuring branch includes an optical transmitter and an optical receiver and the light conductor is optically connected to the optical transmitter and to the optical receiver;
b. the impedance measuring branch includes an AC voltage source, a transimpedance amplifier and a differential amplifier;
c. the shield electrode and non-inverting input of the transimpedance amplifier are connected to the AC voltage source, whereby an AC voltage is applied to the shield electrode; and
d. the differential amplifier subtracts the excitation voltage of the AC voltage source from output of the transimpedance amplifier so that output of the impedance measuring branch is proportional to electrical conductivity of the medium being detected.

9. The needle probe of claim 8, wherein the metallic sheath is formed by metalizing the light conductor.

10. The needle probe of claim 8, wherein the metallic sheath is a stainless steel tube surrounding the light conductor.

11. The needle probe of claim 8, wherein the optical measuring branch further comprises an optical coupler.

12. Method of analyzing a flowing multiphase medium comprising a plurality of phases constituting a plurality of respective components, the method comprising using the needle probe of claim 8 by inserting the distal end of the metal-sheathed light conductor in the mixture thereby to measure, simultaneously, for the medium in contact with said distal end, impedance, by means of the impedance measuring branch of the measuring circuit, and optical characteristics, by means of the optical measuring branch.
